(19) United States
(12) Patent Application Publication
(10) Pub. No.: US 2013/0147552 A1
(43) Pub. Date: Jun. 13, 2013

(54) CLASS-D AMPLIFIER

(71) Applicant: OP Global Holdings Limited, Road Town (VG)

(72) Inventors: Fu-Chieh Hsu, Stateline, NV (US); Mark Shane Peng, Hsinchu County (TW)

(73) Assignee: OP Global Holdings Limited, Road Town (VG)

(21) Appl. No.: 13/674,261

(22) Filed: Nov. 12, 2012

Related U.S. Application Data
(60) Provisional application No. 61/569,850, filed on Dec. 13, 2011.

(51) Int. Cl. H03F 3/217; H03B 28/00

(52) U.S. Cl. CPC H03F 3/2171; H03B 28/00
USPC 330/251; 327/524; 327/596

(57) ABSTRACT

A class-D amplifier includes a quantized amplifier, having no quantization error feedback circuit, coupled to receive a digital input signal, according to which an output signal is generated to be switched between power rails. The digital input signal is pre-compensated to correct an error. A low-pass filter is configured to operate on the output signal to generate a filtered output signal.

### BACKGROUND OF THE INVENTION

1. Field of the Invention

The present invention generally relates to a class-D amplifier, and more particularly to a class-D amplifier with an error being pre-compensated.

2. Description of Related Art

A class-D amplifier or switching amplifier is an electronic amplifier operated as binary switches based on the principle of switching and filtering discrete levels (typically two levels) of current to result in high efficiency of output power. FIG. 1 shows a block diagram of a conventional class-D amplifier 100, which reduces any quantization error related to the discrete output levels with a feedback loop circuitry 11. To achieve high precision and high resolution at the output, the feedback loop circuitry 11 requires a high-precision analog-to-digital conversion (ADC) circuit to generate a precise error signal. The high-precision ADC and associated analog circuitry add significant complexity, power consumption and cost to the class-D amplifier 100 to achieve desired high precision. Furthermore, the feedback loop circuitry 11 may also introduce stability problems under various loading conditions.

For the foregoing reasons, a need has thus arisen to propose a robust, low-cost and stable class-D amplifier to overcome the disadvantages of the conventional class-D amplifier.

### SUMMARY OF THE INVENTION

In view of the foregoing, it is an object of the embodiment of the present invention to provide a class-D amplifier with stored digital input signal that is pre-compensated to correct an error pertained to class-D amplifier in general, therefore improving power efficiency and system stability. The present invention also provides power optimization for an MCU-based mixed signal system through timing of operating modes.

According to one embodiment, a class-D amplifier includes a quantized amplifier and a low-pass filter. The quantized amplifier, having no quantization error feedback circuit, is coupled to receive a digital input signal, according to which an output signal is generated to be switched between power rails. The digital input signal is pre-compensated to correct an error. The low-pass filter is configured to pass low-frequency components of the output signal and attenuate high-frequency components of the output signal, thereby generating a filtered output signal.

According to another embodiment, a microcontroller unit (MCU)-based mixed signal system includes an MCU, a higher frequency circuit, a lower frequency circuit, a higher frequency clock source and a lower frequency clock source. The higher frequency circuit and the lower frequency circuit are controlled under the MCU, the higher frequency circuit operating substantially faster than the lower frequency circuit. The higher frequency clock source and the lower frequency clock source are configured to provide a higher frequency and a lower frequency, respectively. The higher frequency circuit is turned ON for a period of time less than the lower frequency circuit.

### BRIEF DESCRIPTION OF THE DRAWINGS

FIG. 1 shows a block diagram of a conventional class-D amplifier;

FIG. 2 shows a block diagram illustrating a class-D amplifier according to one embodiment of the present invention;

FIG. 3 shows a circuit of a class-D amplifier driving a resistive load; and

FIG. 4 shows a block diagram of an MCU-based mixed signal system according one embodiment of the present invention.

### DETAILED DESCRIPTION OF THE INVENTION

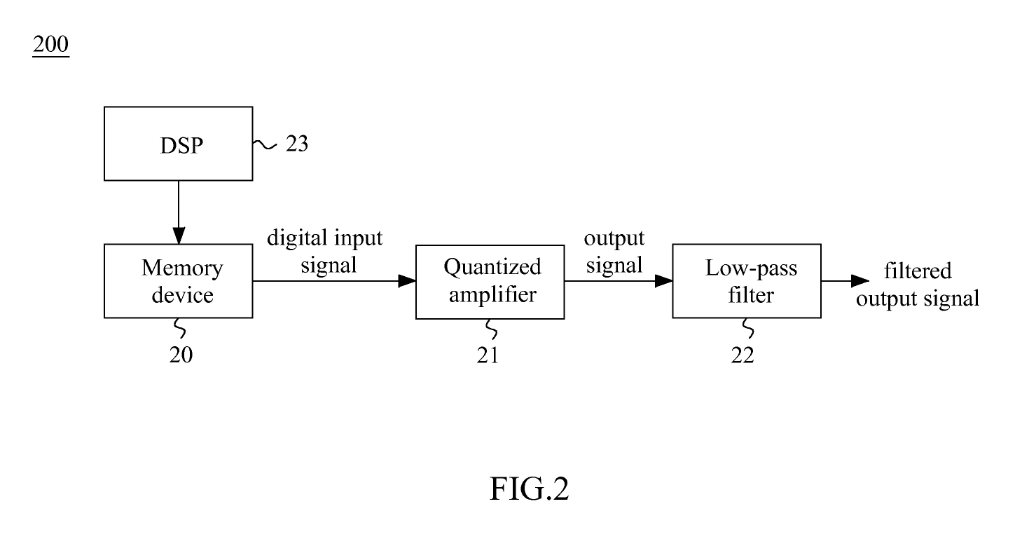

FIG. 2 shows a block diagram illustrating a class-D amplifier 200 according to one embodiment of the present invention. In the embodiment, the class-D amplifier 200 includes a quantized amplifier (or switching controller) 21 that is coupled to receive a digital input signal (or “input signal” for short), according to which an output signal is generated to be switched between power rails. That is, the output signal is switched either fully on or fully off to attain high power efficiency. Although a single-ended configuration is schematically shown in the figure, it is appreciated that other configurations, such as differential (or bridge) output configuration may be used instead. For example, two sets of switching field-effect-transistor (FET) pairs are employed in the differential configuration, instead of employing one set of switching FET pair in the single-ended configuration.

The class-D amplifier 200 also includes a low-pass filter 22 that passes low-frequency components of the output signal and attenuates high-frequency components of the output signal, thereby generating a filtered output signal at an output node of the low-pass filter 22. In the embodiment, the low-frequency components refer to frequency components with frequencies lower than a cutoff frequency, and the high-frequency components refer to frequency components with frequencies higher than the cutoff frequency.

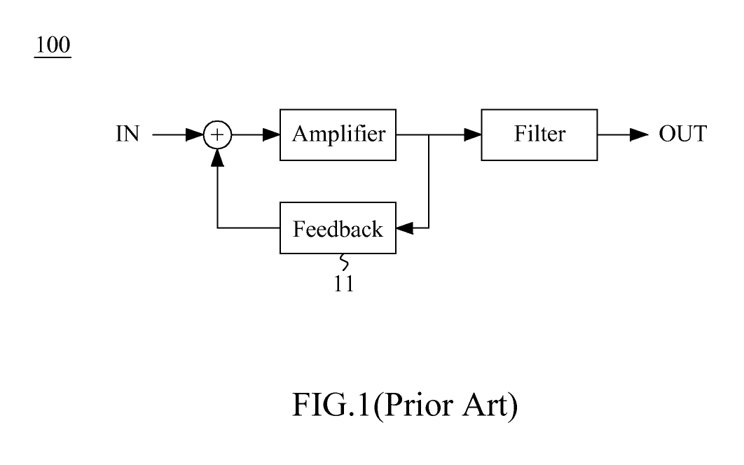

According to one aspect of the embodiment, the digital input signal (that corresponds to a digital waveform) is stored in a memory device 20 beforehand. Moreover, the stored digital input signal is pre-compensated by a digital signal processor (DSP) 23 or any computing device that executes signal processing algorithm to correct an error pertained to class-D amplifier in general. The memory device 20 may be disposed on the same chip as the DSP (or computing device) 23, or on a chip separated from the DSP (or computing device) 23. The error to be corrected may, for example, be a quantization error (or quantization noise). As the quantization error is pre-compensated in the digital input signal, the feedback loop circuitry (11, FIG. 1) adopted in the conventional class-D amplifier (100, FIG. 1) is no longer needed, and stability issues associated with feedback loop circuitry 11 can thus be avoided. As a result, the present embodiment provides a feedback-less class-D amplifier 200, although a feedback loop for other considerations may be optionally adopted.

Specifically, for example, for outputting periodic signals (including any signal stream with finite duration) such as sine waves, the class-D amplifier 200 does not need a feedback loop but can still achieve a high-efficiency, high-precision (low-distortion) output, and most importantly, it can be implemented using cost effective, all digital circuits without any analog precision requirements. And without feedback loop, it is stable under all conditions. The main principle in the preferred embodiment is to appropriately control the output quantization error of the output signal by using a pre-computed input signal stored in the memory device 20. The input signal can be generated ahead of time with “shaped” quantization error. “Shaped” in this sense means the quantization noise level can be controlled in different frequency bands. In terms of signal processing, a loop filter is tailored to affect the quantization noise frequency content. This is extremely beneficial to system implementation with ease and low cost. For example, the quantization error is minimized in low frequency bands which is the band of interest and pushed to the high frequency bands which can be easily filtered by the low-cost low-pass filter 22.

The input signal stored in the memory device 20 can be looped on as long as the ending and beginning are made to be continuous in terms of waveform of the output signal. For example, an integer number of cycles of a sine wave's output value can be stored.

In addition to the aforementioned quantization error to be pre-compensated in the digital input signal stored in the memory device 20, the present invention may be adapted to correct other output errors due to, for example, output quantization step non-linearity, power supply droop, non-linear load, or frequency dependent errors or time varying errors. Although additional error will be introduced due to the periodic nature of the error shaping in the embodiment, it however can be minimized, depending on implementation, to be lower than the other error sources.

In the embodiment, the digital input signal can be generated and shaped, ahead of time, with existing filtering techniques such as delta-sigma modulation. Since these filtering techniques are all performed in the digital domain without any analog degradation, optimal tradeoffs between precision and (over-sampling) memory size (of the memory device 20) and switching rate can be pre-selected based on application's precision requirements. In today's digital world with low-cost memory and digital switching, more memory usage and digital processing is often the most cost effective way to achieve desired analog performance at high output power.

For any finite duration waveform with finite bandwidth of the digital input signal (such as a music piece or a song), the preferred embodiment is suitable for achieving very high fidelity, very high energy efficiency at high output power, using low cost all digital circuitry. For typical audio applications (e.g., playing back audio file) with 20 Hz to 20 KHz bandwidth, an over-sampling frequency of 1 MHz can be selected, and the stored memory size will be 1M bit/sec (without optional compression) compared to conventional input of 0.7 Mbit/sec (44.1 KHz at 16 bits). Higher over-sampling rate and more memory usage can achieve greater precision. Another example is low frequency periodic precision waveform driving high current load (e.g., more than 2 amps) with 16 Hz bandwidth. Using 90 KHz over-sampling rate (90 Kbit/sec), greater than 60 db signal-to-noise ratio (SNR) at full load may be achieved.

Generally speaking, class-D amplifiers work on operation principle of quickly switching the output to preset levels and then filtering output errors associated with the discrete number of preset levels. A major source of error especially for high output power applications is the modification of the preset level based on the input signal. For example, preset levels are voltage references that have finite impedance which causes amplitude dependent droop on the preset levels. When the output requires high current, the preset level has a larger error than when the output requires a low current. A specific example is when the power supplies are used as the two preset output levels in class-D amplifiers.

Given that the input dependent error is often known ahead of time, the digital input signal can be compensated, in the embodiment, by applying an error inverting filter. This technique works even for nonlinear errors, as long as error dependence on the input is well-characterized.

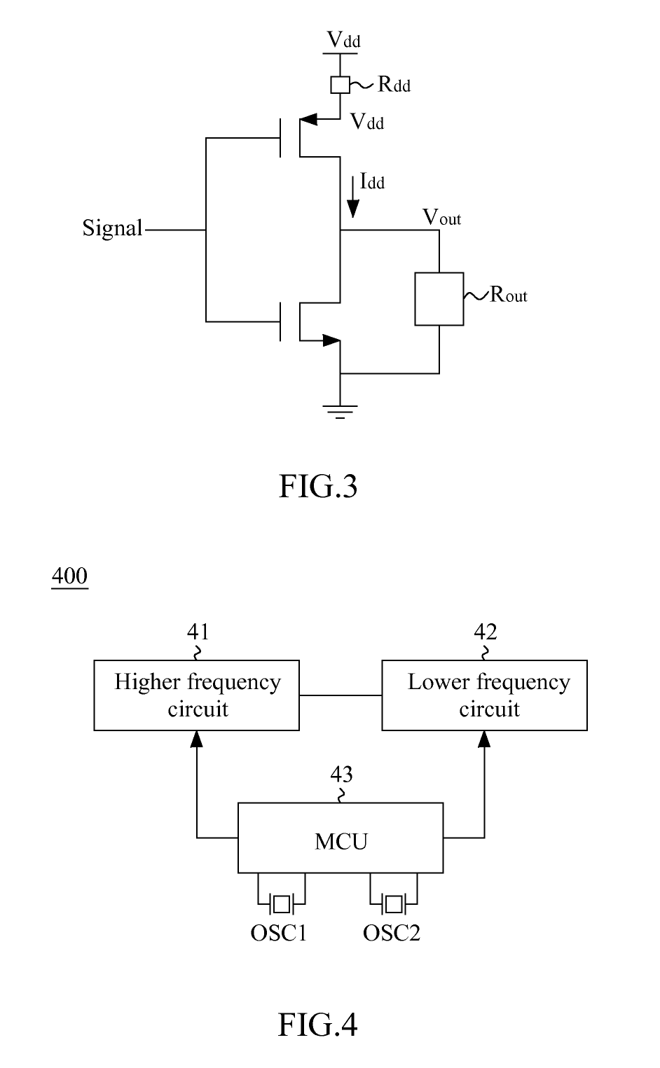

As a specific example, the case of using a non-zero impedance power supply as one of the two preset output levels in a class-D amplifier driving a resistive load is shown in FIG. 3 and analyzed. In the figure, R_{dd} represents the finite impedance of the power supply, V_{dd} represents the ideal power supply and V′_{dd} represents the effective power supply. I_{dd} represents the current from the power supply while Vₒᵤₜ is the output voltage and Rₒᵤₜ is the output load.

The desired output signal, for example, is a pure sine wave and how to compensate the sine wave input signal is given in the following equations (1)-(3) where α represents the amplitude of the desired sine wave relative to the power supply, is the radial frequency, and t is time:

$$\begin{matrix}{V}_{dd}^{′} = {V}_{dd} - {I}_{dd} {R}_{dd} & ( 1 ) \\ {I}_{dd} = \frac{{aV}_{dd}^{′} sin ( ω t )}{{R}_{out}} & ( 2 ) \\ {V}_{out} = \frac{{aV}_{dd} sin ( ω t )}{1 + a \frac{{R}_{dd}}{{R}_{out}} sin ( ω t )} & ( 3 )\end{matrix}$$

The correction factor for the input signal is the denominator of Equation (3) and depends on the output amplitude, power line resistance, and the output resistance of the load device (for example, a coil). The correction factor should be used by multiplying it with the desired signal and applying that to the input of the class-D amplifier 200. Accordingly, in this specific example, the implementation is simple by appropriate scaling of the input signal. However, this technique could be used for more complex types of error as long as the output error dependence on the input signal is well characterized. Furthermore, this technique as demonstrated above may be applicable for differential preset level outputs by appropriate signal inversion. Additionally, this technique could compensate for frequency dependent errors as well by applying this technique in the frequency domain to specific frequencies of interest. In principle, this technique could be applicable for time variant errors as well where the input compensation would be time variant as well. It is noted that the technique discussed above may work for class-D amplifiers 200 with or without feedback for the rationale that the compensation is applied to the input signal.

According to another aspect of the invention, the embodiment for a mixed signal system in general, may be controlled by a microcontroller unit (MCU) that periodically operates (turns ON) certain analog modules, that also turns ON more power hungry/draining digital processing cores during the analog operation. To minimize overall power in these cases, analog operations should be finished as quickly as possible, and the entire MCU should be put in the lowest power mode possible.

For example, in a MCU-based mixed signal system that periodically sensing an Electroencephalography (EEG) bio-signal, an analog-to-digital converter (ADC) is run with fastest clock possible so that it can finish its conversion process quickly and then put into a sleep mode that saves as much power as possible. Only when the next conversion is necessary is the MCU awaken and the ADC conversion takes place again. This saves much more power than running the ADC with a slower clock since the digital section must remain ON during this conversion time. Similarly, the communication module (such as RF circuitry) should be run with fastest clock possible so that it can finish its packet transmission quickly and then put into a sleep mode that saves as much power as possible. Only when the next transmission is necessary is the MCU awaken and the communication transmission takes place again. This saves much more power than running the communication with a slower clock since the digital section must remain ON during this transmission time. A memory storage module, and sensors (such as accelerometer, gyroscope, temperature sensor, etc.) should also be turned ON and OFF in a similar way to save power.

FIG. 4 shows a block diagram of an MCU-based mixed signal system 400 according one embodiment of the present invention. In the embodiment, the system 400 includes at least two circuits 41 and 42 controlled under an MCU 43. In the embodiment, there are at least two circuits 41 and 42 including a higher frequency circuit 41 and a lower frequency circuit 42, where the higher frequency circuit 41 operates faster, e.g., at least 10 times faster, than the lower frequency circuit 42. The higher frequency circuit 41 may be, but not limited to, a data conversion circuit (e.g., ADC), a communication circuit, a storage circuit or a sensor circuit.

In the preferred embodiment, at least two clock frequencies, provided, for example, by two clock sources (a higher frequency clock source OSC1 and a lower frequency clock source OSC2) such as crystal oscillators, are operable in the system 400 to implement such fast-ON, fast-OFF energy-saving operation modes. The higher frequency clock (such as 16 MHz) source OSC1 may be turned ON and OFF as required to save power, and the lower frequency clock (such as 32.768 KHz) source OSC2 may be ON all the time to keep the system 400 operating in low power mode and for scheduling the turning ON and OFF of the higher frequency circuit 41. In one exemplary embodiment, the higher frequency clock source OSC1 operates typically between 10 MHz and 40 MHz, and the lower frequency clock source OSC2 operates typically between 10 KHz and 1 MHz.

In one embodiment, the higher frequency circuit 41 is turned ON for less than 15% of the time, and the lower frequency circuit 42 is turned ON for 85% of the time or more. For example, the ADC circuit needs only be turned on for less than 10% of the time, the RF circuit for less than 1% of the time, and the storage circuit or the sensor circuit for less than 5% of the time.

Although specific embodiments have been illustrated and described, it will be appreciated by those skilled in the art that various modifications may be made without departing from the scope of the present invention, which is intended to be limited solely by the appended claims.

What is claimed is:

1. A class-D amplifier, comprising:
a quantized amplifier, having no quantization error feedback circuit, coupled to receive a digital input signal, according to which an output signal is generated to be switched between power rails, said digital input signal being pre-compensated to correct an error; and
a low-pass filter configured to pass low-frequency components of the output signal and attenuate high-frequency components of the output signal, thereby generating a filtered output signal.

2. The class-D amplifier of claim 1, wherein the quantized amplifier has a differential output configuration.

3. The class-D amplifier of claim 2, wherein the quantized amplifier comprises two sets of switching field-effect-transistor (FET) pairs.

4. The class-D amplifier of claim 1, further comprising a memory device configured to store said digital input signal.

5. The class-D amplifier of claim 1, further comprising a computing device configured to compute said digital input signal to correct the error.

6. The class-D amplifier of claim 5, wherein the computing device comprises a digital signal processor (DSP).

7. The class-D amplifier of claim 5, wherein said computing device pre-compensates the digital input signal by minimizing the to-be-corrected error in low frequency bands.

8. The class-D amplifier of claim 5, wherein said computing device pre-computes to pre-compensate the digital input signal for playing back audio file.

9. The class-D amplifier of claim 5, wherein said computing device pre-computes to pre-compensate the digital input signal for driving a current load.

10. The class-D amplifier of claim 1, wherein the error to be corrected is a quantization error, a frequency dependent error or a time varying error.

11. The class-D amplifier of claim 1, wherein the error to be corrected is an error due to output quantization step non-linearity, power supply droop or non-linear load.

12. The class-D amplifier of claim 1, wherein said quantized amplifier comprises all digital circuits.

13. A microcontroller unit (MCU)-based mixed signal system, comprising:
an MCU;
a higher frequency circuit and a lower frequency circuit controlled under the MCU, the higher frequency circuit operating substantially faster than the lower frequency circuit;
a higher frequency clock source and a lower frequency clock source configured to provide a higher frequency and a lower frequency, respectively;
wherein the higher frequency circuit is turned ON for a period of time less than the lower frequency circuit.

14. The system of claim 13, wherein he higher frequency circuit operates at least 10 times faster than the lower frequency circuit.

15. The system of claim 13, wherein the higher frequency circuit comprises at least one of the following circuits: a data conversion circuit, a communication circuit, a storage circuit, a sensor circuit and combination thereof.

16. The system of claim 13, wherein the higher and lower frequency clock sources comprise crystal oscillators.

17. The system of claim 13, wherein the higher frequency clock source operates between 10 MHz and 40 MHz, and the lower frequency clock source operates between 10 KHz and 1 MHz.

18. The system of claim 13, wherein the higher frequency circuit is turned ON for less than 15% of a specified period of time, and the lower frequency circuit is turned ON for 85% or more of the specified period of time.

19. The system of claim 13, wherein the lower frequency circuit schedules the turning ON and OFF of the higher frequency circuit.
